(19) United States
(12) Patent Application Publication
(10) Pub. No.: US 2008/0309431 A1
(43) Pub. Date: Dec. 18, 2008

(54) PLANAR EMI FILTER

(75) Inventors: Ron Shu Yuen HUI, Hong Kong (CN); Chi Kwan LEE, Hong Kong (CN); Xun LIU, Guizhou (CN)

Correspondence Address: HESLIN ROTHENBERG FARLEY & MESITI PC, 5 COLUMBIA CIRCLE, ALBANY, NY, 12203, US

(73) Assignee: CITY UNIVERSITY OF HONG KONG, Hong Kong (CN)

(21) Appl. No.: 11/763,638

(22) Filed: Jun. 15, 2007

(51) Int. Cl. H03H 7/00; H04B 3/56

(52) U.S. Cl. 333/181; 333/12

(57) ABSTRACT

An EMI filter for use between a power source and an electronic product is formed of at least one planar element including a pair of opposed coreless spiral planar windings, and a planar capacitor. This enables the integration of common mode and differential mode filters into integrated planar structures.

### FIELD OF THE INVENTION

This invention relates to a planar EMI filter, and in particular to such a filter suitable for use with ultra-high frequency power converters.

### BACKGROUND OF THE INVENTION

EMI filters are routinely provided with electrical and electronic devices to ensure that any electromagnetic noise generated by the device is not allowed to pass back into the mains power supply. Generally such filters are classed as being either differential mode (DM) filters comprising inductive elements in the live and neutral lines, or common mode (CM) filters comprising capacitive elements between the live and neutral lines and ground.

Traditionally EMI filters are constructed by conventional circuit components including in particular discrete capacitive and inductive components provided on a circuit board. However, with increasing miniaturization of electronic components such EMI filters may become disproportionately large with respect to the associated circuits and components that are being filtered. There is therefore a need for more compact EMI filter designs, and in particular for EMI filters that can be integrated with other electronic components in an electronic device.

Known in the art are coreless planar spiral windings (CPSW) that may be used in coreless transformers. A CPSW may be formed in a number of ways, for example by depositing conductive tracks on a printed circuit board and when used in a coreless transformer for signal and/or power transfer primary and secondary windings may be formed as CPSWs on opposing sides of a suitable dielectric substrate. In addition to their use in coreless transformers for power and signal transfer, such planar spiral windings have also been proposed for use in integrated EMI filters with the help of ferrite materials. Coupled coreless planar spiral windings have also been proposed to cancel the capacitor parasitic inductance in traditional EMI filters. It has also been known to use CPSW as the inductive elements in differential mode EMI filters, but such prior proposals have always continued to use discrete three-dimensional capacitors that prevent complete integration of the EMI filter structure.

### SUMMARY OF THE INVENTION

According to the present invention there is provided an EMI filter for use between a power source and an electronic product, wherein the EMI filter comprises at least one planar element comprising a pair of opposed coreless spiral planar windings, and a planar capacitor.

In one embodiment, the planar windings are formed on opposed sides of a substrate, such as for example a printed circuit board.

The planar capacitor may comprise at least two parallel conductive plates spaced apart by a dielectric material.

The filter is, in one embodiment, a combined conductive mode filter and differential mode filter. In such an embodiment the conductive mode filter may comprise a first planar element, and the differential mode filter may comprises two planar elements symmetrically disposed in the phase and neutral lines between the power source and the product.

There are a number of possible configurations for such a combined common mode and differential mode filter.

For example, in some embodiments the common mode filter is provided adjacent to the power source and the differential mode filter is provided adjacent to the product. In these embodiments, the planar capacitor may be provided between the common mode filter and the differential mode filter, or between the differential mode filter and the product, or between the power source and the common mode filter.

Alternatively, the differential mode filter may be provided adjacent to the power source and the common mode filter may be provided adjacent to the product. In these embodiments, the planar capacitor may be provided between the power source and the differential mode filter, or between the differential mode filter and the common mode filter, or between the common mode filter and the product.

### BRIEF DESCRIPTION OF THE DRAWINGS

Some embodiments of the present invention are described below by way of example and with reference to the accompanying drawings, in which:

FIG. 1 shows schematically two coreless planar spiral windings and their equivalent circuit;

FIG. 2 shows schematically the role of an EMI filter;

FIGS. 3a and 3b illustrate two examples of the use of a coreless planar spiral winding as a direct mode filter;

FIG. 4 shows an example of a planar capacitor as may be used in embodiments of the invention,

FIG. 5 shows an example of a common mode filter according to an embodiment of the invention;

FIG. 6 shows a conventional combined CM and DM EMI filter;

FIG. 7 shows a combined CM and DM EMI filter according to an embodiment of the invention;

FIG. 8 shows a combined CM and DM EMI filter according to another embodiment of the invention;

FIG. 9 shows a combined CM and DM EMI filter according to another embodiment of the invention;

FIG. 10 shows a combined CM and DM EMI filter according to another embodiment of the invention;

FIG. 11 shows a combined CM and DM EMI filter according to another embodiment of the invention, and

FIG. 12 shows a combined CM and DM EMI filter according to another embodiment of the invention.

### DETAILED DESCRIPTION OF PREFERRED EMBODIMENTS

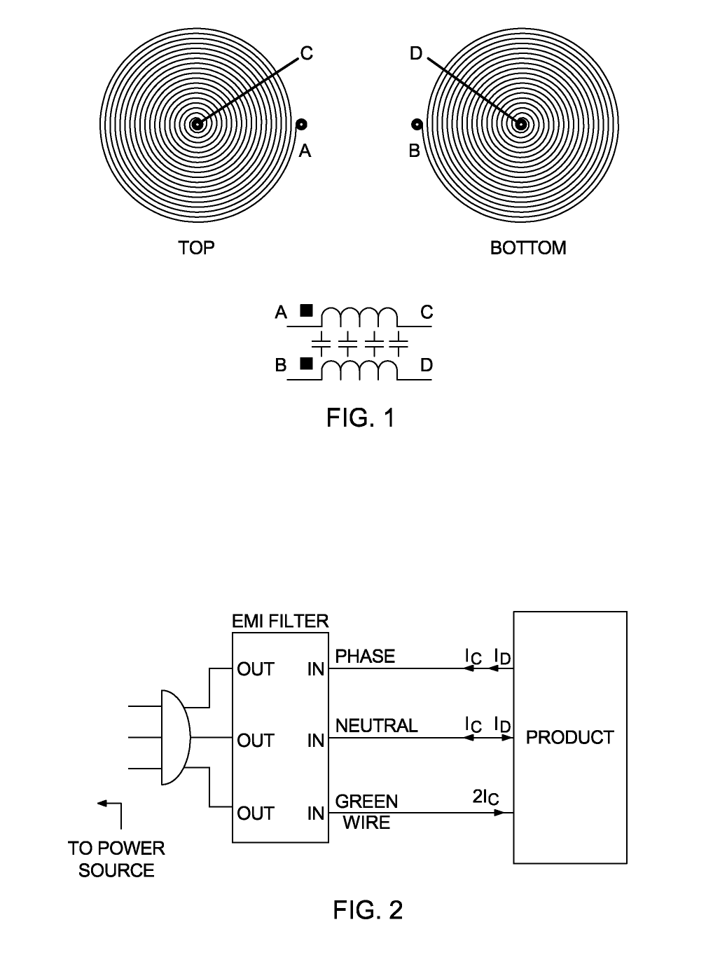

FIG. 1 shows two conventional spiral windings. The dimensions and number of turns of the windings may vary depending on the intended application. The windings can be constructed with printed circuit board (PCB) or other substrates such as semiconductor materials. For construction in the PCB, the windings may be formed on opposed sides of a PCB substrate, eg 0.4 mm thick and may form the primary and secondary coils of a coreless transformer as is known in the art. For convenience of description throughout this specification the ends of the top coil may be labeled A and C, while the corresponding ends of the bottom coil may be labeled B and D. As shown in FIG. 1, when placed on opposite sides of a substrate the two planar spiral windings may be represented electrically as two inductances with a capacitive component between them.

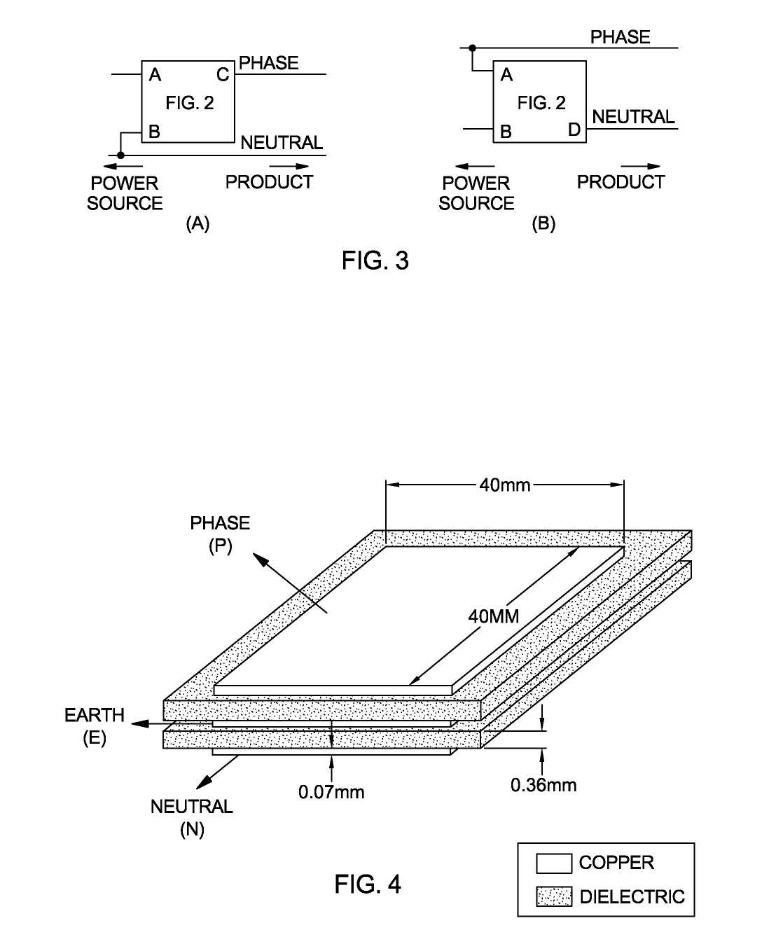

FIG. 2 shows a simple block diagram of the function of an EMI filter. The function of the EMI filter is to block and/or divert the conducted emission current in common mode (I_{C}) and differential mode (I_{D}) so that they do not enter the power source.

FIG. 3a shows how two planar spiral windings formed on opposed sides of a substrate may be employed as a DM filter added on the phase line. Using the nomenclature of FIG. 1 the phase line from the power source is connected at A and the phase line from the filter to the device goes from C. Point B is connected to earth. FIG. 3b shows how the same windings can be employed as a DM filter added on the neutral line. In this example, point A is connected alone to the phase line, while the neutral line from the power source is connected at point B and the neutral line goes from point D to the device.

An aspect of the present invention, at least in various embodiments, is the integration of planar CM and DM filter elements with planar capacitive elements such that the complete filter structure can be more easily integrated in its own design and also with other circuit elements. In this connection embodiments of the invention may employ one or more planar capacitors an example of which is shown in FIG. 4. As shown in FIG. 4, this planar capacitor may comprise three planar copper layers in a sandwich-like structure separated by dielectric layers. The three copper layers may respectively be connected to the phase, earth and neutral lines as may be required in any particular circuit diagrams. By way of example only, typical dimensions may be 40 mm×40 mm×0.07 mm for the copper layers, and a thickness of 0.36 mm for the interleaving dielectric layers. The dielectric material may be a simple PCB substrate, or may be a material of higher permittivity if a higher capacitance is required.

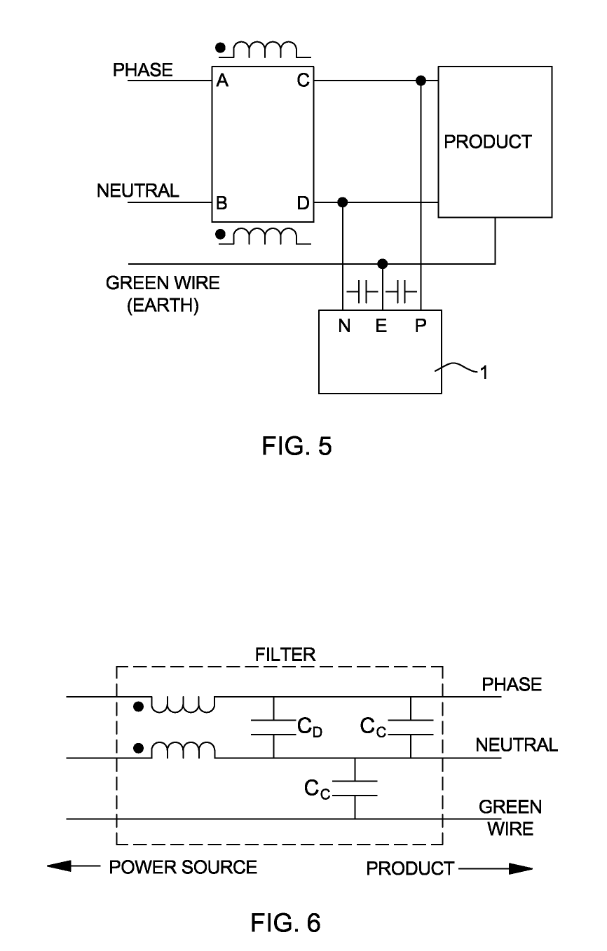

FIG. 5 shows how a planar capacitor 1 may be used in conjunction with a planar spiral winding structure to form a common mode filter. The planar spiral windings are connected in the phase and neutral lines between the power source and the product with the phase line from the power source being connected at A and the phase line extending to the product from C. Similarly the neutral line from the power source is connected at B and the neutral line continues to the product from D. A planar capacitor 1 constructed as shown in FIG. 4 is connected between the spiral windings and the product, with the neutral, phase and earth layers of the capacitor 1 being connected to the respective neutral, phase and earth lines.

The examples above show DM and CM filters separately, but they may be combined in a single EMI filter. FIG. 6 shows how this is done in an EMI filter. A conventional combined filter normally consists of a CM choke as well as CM capacitors and a DM capacitor as shown in FIG. 6. Such a conventional design can be looked at as a CM filter with a DM capacitor added, but when a CM choke is used in a DM filter only a very small leakage inductance remains effective for filtering because of flux cancellation and so a large capacitor CD is needed to achieve the required filtering effect. Providing such a large capacitance in a planar capacitor structure as shown in FIG. 4 requires either an undesirably large area, or a dielectric material of high permittivity.

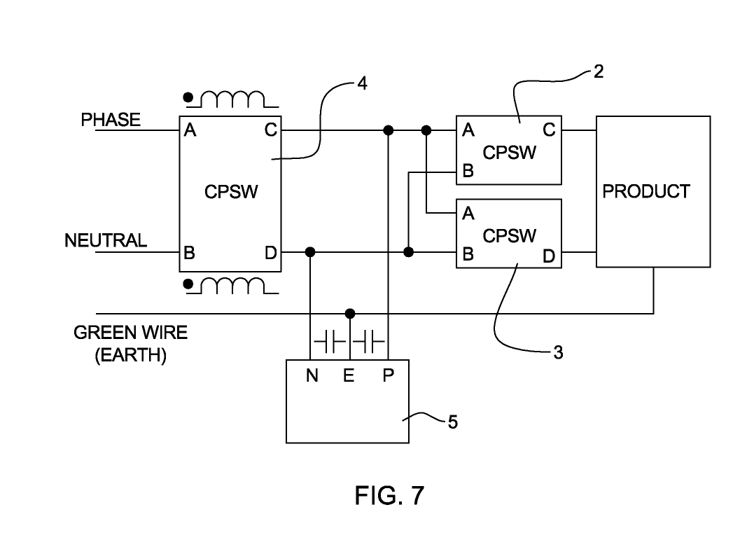

FIG. 7 shows a combined CM and DM filter using planar spiral windings and planar capacitors that mitigate this problem. In this embodiment, two DM filters 2,3 respectively are employed of the forms shown in FIG. 3a and FIG. 3b and with filter 2 added to the phase line and filter 3 added to the neutral line. These two DM filters provide the DM EMI filtering while retaining filter circuit symmetry. CM filtering is provided by CM filter 4 which is of the form shown in FIG. 5 including the planar capacitor 5. It will be noted that terminal C in the CM filter—which is in the phase line—connects to terminals A in both the DM filters, while terminal D in the CM filter—which is in the neutral line—connects to terminals B in the DM filters. One advantage of this circuit design is that the capacitive elements in the CM filter—both the planar capacitor and the distributed capacitance in the spiral windings—contribute to the overall DM filtering.

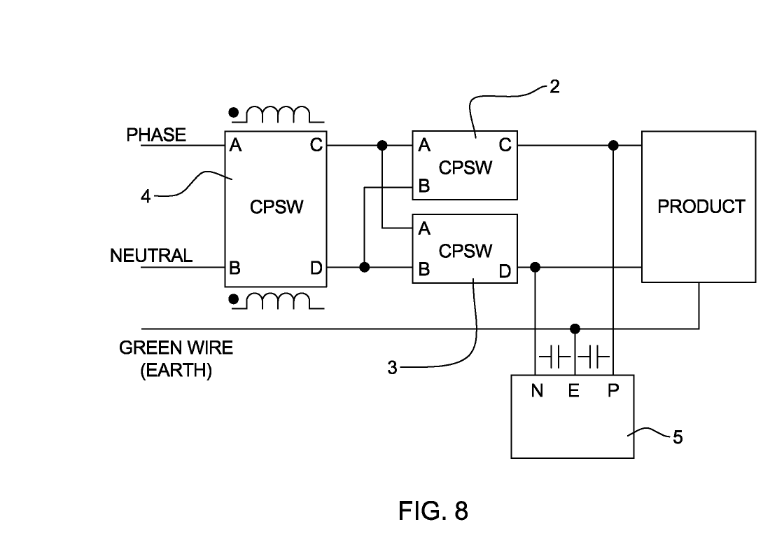

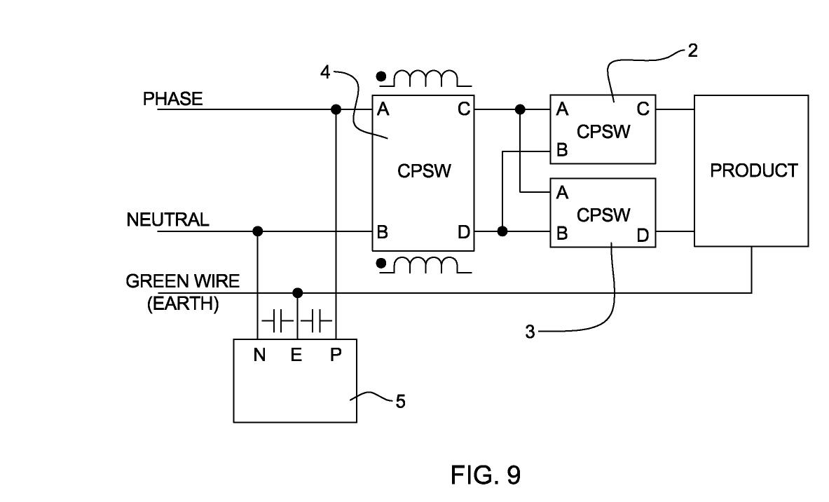

Viewed in the direction of from the power source to the product, the combined filter of FIG. 7 may be considered to have the structure CM choke+C+DM filter. FIG. 8 shows a modification of the embodiment of FIG. 7, in which instead of being provided between the CM and DM spiral windings, the planar capacitor 5 is provided between the DM filters the electrical product. This structure is therefore CM choke+DM filter+C. A further possibility is the sequence C+CM choke+DM filter as shown in FIG. 9 where the planar capacitor is located between the power source and the CM choke.

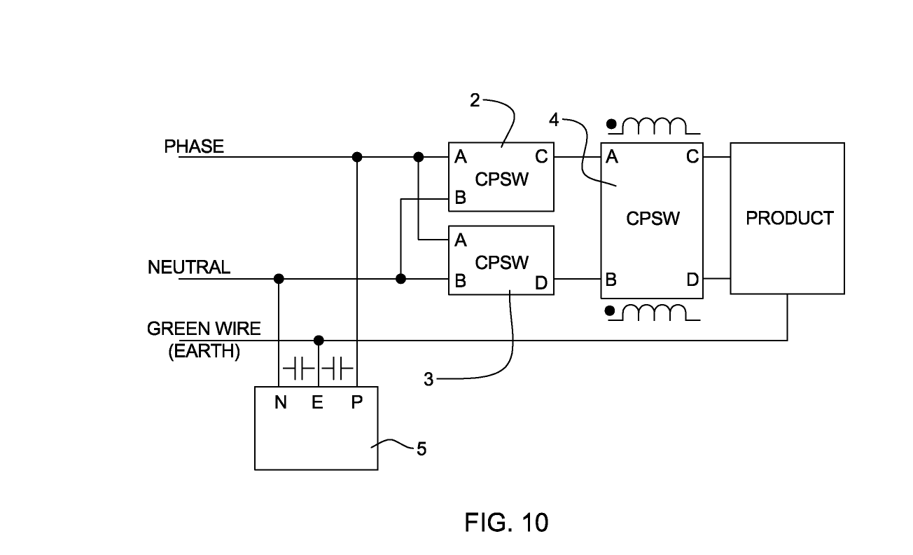

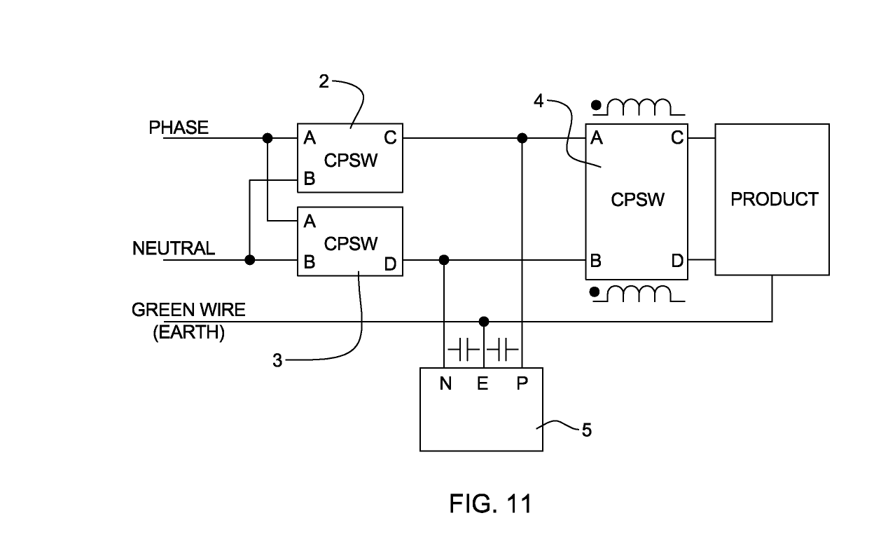

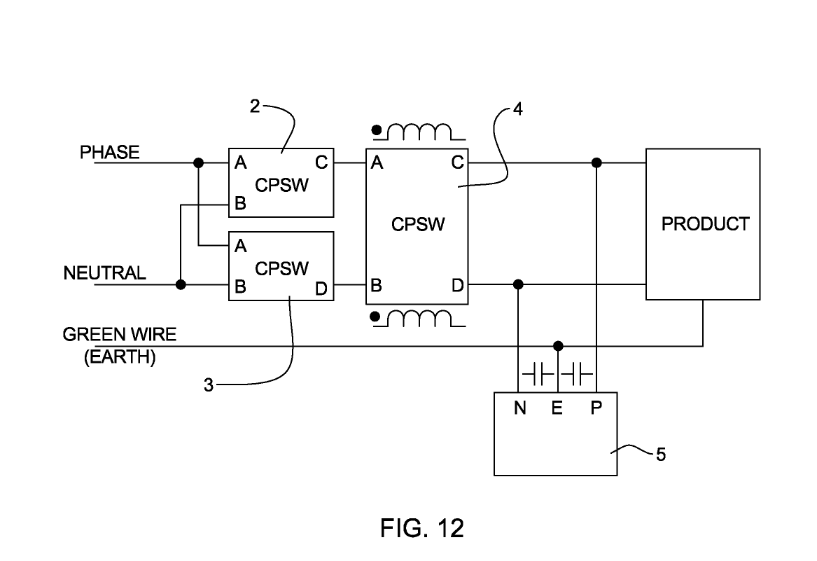

It is also possible for the DM filters to be located on the source side and the CM choke to be located on the product side. This possibility is shown in the embodiments of FIGS. 10 to 12, which differ in terms of location of the planar capacitor. FIG. 10 has the structure C+DM filter+CM choke with the planar capacitor being located between the power source and the DM filter. In FIG. 11, the planar capacitor is located between the DM filter and the CM choke, ie DM filter+C+CM choke, while in FIG. 12 the planar capacitor is located between the CM choke and the product, that is, the structure is DM filter+CM choke+C.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. An EMI filter for use between a power source and an electronic product, said EMI filter comprising at least one planar element comprising a pair of opposed coreless spiral planar windings, and a planar capacitor.

2. The filter of claim 1, wherein said planar windings are formed on opposed sides of a substrate.

3. The filter of claim 2, wherein said substrate is a printed circuit board.

4. The filter of claim 1, wherein said planar capacitor comprises at least two parallel conductive plates spaced apart by a dielectric material.

5. The filter of claim 1, wherein said filter is a combined conductive mode filter and differential mode filter.

6. The filter of claim 1, wherein said conductive mode filter comprises a first said planar element, and wherein said differential mode filter comprises two said planar elements symmetrically disposed in the phase and neutral lines between the power source and the product.

7. The filter of claim 6, wherein said common mode filter is provided adjacent the power source and the differential mode filter is provided adjacent the product.

8. The filter of claim 7, wherein the planar capacitor is provided between the common mode filter and the differential mode filter.

9. The filter of claim 7, wherein the planar capacitor is provided between the differential mode filter and the product.

10. The filter of claim 7, wherein the planar capacitor is provided between the power source and the common mode filter.

11. The filter of claim 6, wherein the differential mode filter is provided adjacent to the power source and the common mode filter is provided adjacent to the product.

12. The filter of claim 11, wherein the planar capacitor is provided between the power source and the differential mode filter.

13. The filter of claim 11, wherein the planar capacitor is provided between the differential mode filter and the common mode filter.

14. The filter of claim 11, wherein the planar capacitor is provided between the common mode filter and the product.
